(19) United States
(12) Patent Application Publication
(10) Pub. No.: US 2026/0304726 A1
(43) Pub. Date: Oct. 1, 2026

(54) CONDUCTIVE FILM AND METHOD FOR PRODUCING THE SAME

(71) Applicant: SEIREN CO., LTD., Fukui (JP)

(72) Inventors: Takayuki NOSAKA, Fukui (JP); Masatoshi GOTO, Fukui (JP); Koki TSUGE, Fukui (JP)

(21) Appl. No.: 19/456,319

(22) Filed: Jan. 22, 2026

(30) Foreign Application Priority Data
Dec. 2, 2024 (JP) 2024-209830

(51) Int. Cl. H05K 9/00

(52) U.S. Cl. CPC H05K 9/0088; H05K 9/0084

(57) ABSTRACT

An object of the present invention is to provide a lightweight conductive film useful for an electromagnetic wave shielding material, which does not cause cracks in the metal layer even when subjected to molding processing. A conductive film having a resin film and a metal layer wherein the ratio of the amount of copper applied per unit area (g/m²) to the amount of tin applied per unit area (g/m²) [Cu/Sn] is 0.15 or less, and the average grain size of the tin crystals constituting the tin layer is 5.0 μm or more is obtained by laminating a copper layer and a tin layer in this order on at least one side of a resin film.

### TECHNICAL FIELD

The present invention relates to a conductive film. More particularly, the present invention relates to a lightweight conductive film useful for an electromagnetic wave shielding material, which does not cause cracks in the metal layer even when subjected to molding processing.

### BACKGROUND ART

In recent years, with the rapid development of IT equipment and office automation equipment, the influence of electromagnetic waves generated from electronic equipment, cables, motors, and inverters on other electronic equipment and information equipment has become a problem.

Electromagnetic waves not only cause malfunctions of precision equipment, but also cause a concern about the influence on human bodies. For this reason, various technologies have been developed to reduce the effect of electromagnetic waves by using electromagnetic wave shielding materials. Example of the electromagnetic wave shielding materials include a laminate formed by laminating a metal layer having electromagnetic wave shielding properties, such as copper foil, on a resin film.

However, laminates in which a metal layer is laminated on a resin film are prone to cracking during molding. Therefore, it is necessary to suppress cracking and improve molding processability.

Examples of methods for suppressing cracking include increasing the thickness of the metal layer or the number of metal layers laminated. However, such methods cause the increase of the weight, making it difficult to achieve excellent lightweight properties. It is not easy to satisfy both lightweight properties and moldability at the same time.

Various proposals have been made regarding electromagnetic wave shielding materials in which a metal layer is laminated on a resin film. For example, Patent Document 1 discloses an electromagnetic wave shielding material in which resin layers are tightly laminated on both sides of a metal foil to suppress breakage during molding. This material is designed to enhance the ductility of the metal foil, but has the disadvantage that soldering is not possible because the metal foil is sandwiched between resin layers.

Patent Document 2 discloses that an electromagnetic wave shielding material with excellent three-dimensional moldability and lightweight properties can be obtained by laminating a resin layer on a copper foil and specifying the degree of orientation of the copper foil surface and the relationship between the thickness of the copper foil and the thickness of the resin layer. However, this method has the disadvantage that it requires producing copper foil with a specific degree of orientation and thickness, and then laminating multiple layers of copper foil and resin layers, making the process complicated.

Patent Document 3 discloses an electromagnetic wave shielding material in which multiple metal layers and insulating layers are alternately laminated to prevent cracks in the metal layers during molding. However, this material tends to be thicker and requires an increase of manufacturing process.

Patent Document 4 discloses a conductive film obtained by laminating copper and tin in this order on a film substrate, and this film improves solder wettability by providing a barrier layer made of an organic compound between the copper layer and the tin layer.

### PRIOR ART DOCUMENTS

### Patent Document

Patent Document 1: Jpn. Pat. Kokai (unexamined laid-open publication) No. 2018-152466
Patent Document 2: Jpn. Pat. Kokai No. 2021-163789
Patent Document 3: Jpn. Pat. Kokai No. 2022-091579
Patent Document 4: International Publication No. WO2022/085374

### DISCLOSURE OF THE INVENTION

### Problems to be Solved by the Invention

An object of the present invention is to provide a conductive film excellent in lightweight properties, capable of preventing the occurrence of cracks in the metal layer even when subjected to molding processing, and useful as an electromagnetic wave shielding material.

### Means for Solving the Problems

To solve the above problems, the inventors have found that the above problems can be solved by providing a laminate in which a copper layer and a tin layer are laminated in this order on a resin film wherein the ratio of the application amount of copper to the application amount of tin and the average grain size of the tin crystals constituting the tin layer satisfy certain conditions, and have completed the present invention.

That is, the present invention relates to the following conductive film:
(1) A conductive film having a resin film and a metal layer in which a copper layer and a tin layer are laminated in this order on at least one surface of said resin film, wherein the ratio of the amount of copper applied per unit area (g/m²) to the amount of tin applied per unit area (g/m²) [Cu/Sn] is 0.15 or less, and the average grain size of the tin crystals constituting the tin layer is 5.0 μm or more.
(2) The conductive film according to (1), wherein the amount of copper applied per unit area in said copper layer is 10 g/m² or less.
(3) The conductive film according to (1), wherein the arithmetic mean roughness Ra of the surface of said tin layer is 0.25 μm or more.
(4) The conductive film according to (1), wherein the thickness of said resin film is in the range of 100 to 200 μm.
(5) A method for producing the conductive film according to any one of (1) to (4), which comprises a step of forming a copper layer on a resin film and a step of forming a tin layer by electrolytic tin plating on said copper layer formed in the previous step.
(6) The method for producing the conductive film according to (5), wherein a non-glossy tin plating solution is used as the plating solution for said electrolytic tin plating.

### Effect of the Invention

According to the present invention, a conductive film excellent in lightweight properties, capable of preventing the occurrence of cracks in the metal layer even when subjected to molding processing, and useful as an electromagnetic wave shielding material can be obtained.

### BRIEF DESCRIPTION OF THE DRAWINGS

FIG. 1 shows a cross-sectional view illustrating an outline of an embodiment of a conductive film of the present invention.

FIG. 2 shows a plan view showing an outline of a jig and a sample used in the evaluation of moldability in the examples.

FIG. 3 shows a cross-sectional view and a schematic diagram showing an outline of a jig for fixing the sample for evaluation used for the evaluation of moldability in the examples.

FIG. 4 shows a cross-sectional view schematically illustrating a molding process for the evaluation of moldability in the examples.

FIG. 5 shows a schematic diagram illustrating a conductive film sample after molding which is a molded product for evaluation in the examples.

FIG. 6 shows a digital microscope image of the conductive film produced in Example 1, observing the presence or absence of metal cracks in the evaluation of moldability.

FIG. 7 shows a digital microscope image used to measure the crystal grain size of the tin layer of the conductive film produced in Example 1.

FIG. 8 shows a digital microscope image of the conductive film produced in Comparative Example 5, observing the presence or absence of metal cracks in the evaluation of moldability.

FIG. 9 shows a digital microscope image of the conductive film produced in Comparative Example 5, observing the presence or absence of light leakage in the evaluation of moldability.

### MODES FOR CARRYING OUT THE INVENTION

The conductive film of the present invention comprises at least a resin film and a metal layer formed on the resin film.

### 1. Resin Film

The resin film is preferably a film made of a synthetic resin. Examples of the synthetic resins include, but are not limited to, polyethylene terephthalate, polybutylene terephthalate, polyethylene naphthalate, polyethylene, polypropylene, polyimide, polyetherimide, and polyphenylene sulfide.

More preferably, the resin film has an elastic modulus of 3.0 GPa or more. The tensile strength thereof is preferably 70 MPa or more, more preferably 75 MPa or more, and particularly preferably 100 MPa or more. The glass transition point thereof is preferably 90° C. or more, more preferably 150° C. or more. The melting point thereof is preferably 270° C. or more, more preferably 300° C. or more.

Resin films that satisfy these conditions provide advantages such as high film strength and resistance to breakage, excellent heat resistance, and resistance to thermal distortion that might occur during the reflow process after molding, making them suitable for use as materials having excellent moldability and strength in the present invention.

Especially, polyetherimide (PEI) and polyphenylene sulfide (PPS) are particularly preferred as materials for the resin film.

The thickness of the resin film is not particularly limited, but is preferably in the range of 100 to 200 μm. When the thickness of the resin film is within this range, moldability can be improved.

When the thickness is 100 μm or more, the film is less likely to break and handling properties do not deteriorate. Furthermore, sufficient strength can be maintained after molding.

When the thickness is 200 μm or less, the film can be followed to the mold without any difficulty during molding.

### 2. Metal Layer

The metal layer formed on the resin film includes at least a copper layer and a tin layer. The metal layer may be formed on only one side of the resin film or on both sides.

### (1) Copper Layer

The copper layer is formed on at least one surface of the resin film in contact with the resin film. In the present invention, the copper layer includes not only a layer consisting of metallic copper alone, but also a layer consisting of a copper alloy. That is, the metal forming the copper layer may be either copper alone or a copper alloy. Examples of copper alloys include alloys of copper with metals such as nickel, zinc, and tin. The proportion of copper in the copper alloy is not particularly limited. It is preferable that the copper layer is consisting of copper alone.

The amount of copper applied per unit area (g/m²) in the copper layer is not particularly limited, but is preferably 10.0 g/m² or less. When the amount of copper applied is within the above range, metal cracking during molding tends to be less likely to occur. The lower limit of the amount of copper applied is not particularly limited, but is preferably 3.0 g/m² or more.

The thickness of the copper layer is not particularly limited, but is preferably 1.0 μm or less. The lower limit of the thickness is not particularly limited, but is preferably 0.1 μm or more, more preferably 0.3 μm or more. When the thickness of the copper layer is within the above range, a conductive film excellent in flexibility and moldability while maintaining sufficient conductivity can be obtained.

The copper layer may be consisting of a single layer or two or more copper layers being laminated. The number of copper layers is preferably 1 to 2. When two or more copper layers are laminated, they may have the same or different properties and/or may be formed by the same or different method. The plural layers having the same composition of the constituent materials with each other are considered to be one layer. When plural copper layers are laminated, the preferred range of the total amount and thickness of the multiple laminated copper layers can be same as the above-described preferred range of metal application amount and thickness of the copper layer.

The copper layer can be formed on the resin film by any known method without limitation. Examples of the formation methods include a method of attaching copper foil using an adhesive, a dry film formation method such as a vacuum deposition method or a sputtering method, and a wet film formation method such as electroless plating or electroplating. The copper layer may also be formed by a combination of these methods. Among them, preferred methods include the dry film formation method and the wet film formation method. Alternatively, a resin film on which a copper layer has already been formed, including a commercially available product, can also be used.

When the copper layer is a single layer, the amount of copper applied per unit area (g/m²) in the copper layer is not particularly limited, but is preferably 10.0 g/m² or less, more preferably 5.0 g/m² or less. The lower limit of the amount of copper applied is not particularly limited, but is preferably 3.0 g/m² or more.

The thickness of the copper layer is not particularly limited, but is preferably 0.5 μm or less. The lower limit of the thickness is not particularly limited, but is preferably 0.1 μm or more, more preferably 0.3 μm or more. When the thickness of the copper layer is within the above range, a conductive film excellent in flexibility and moldability while maintaining sufficient conductivity can be obtained.

### (2) Tin Layer

In the present invention, the tin layer is laminated in contact with the copper layer on the side opposite to the resin film side of the copper layer.

The amount of tin applied per unit area (g/m²) in the tin layer is not particularly limited, but is preferably 20 g/m² or more, more preferably 30 g/m or more. A larger amount of tin applied tends to improve moldability. The upper limit of the amount of tin applied is not particularly limited, but is preferably 110 g/m² or less, more preferably 80 g/m² or less. When the amount of tin applied in the tin layer is within the above range, a conductive film excellent in moldability can be obtained.

The thickness of the tin layer is not particularly limited, but is preferably 5 μm or more, and more preferably 7.5 μm or more. The upper limit of the thickness of the tin layer is not particularly limited, but is preferably 20 μm or less, more preferably 15 μm or less. When the thickness of the tin layer is within this range, metal cracks tend to be less likely to occur during molding, and a conductive film excellent in moldability can be obtained.

The tin layer may be a single layer, or two or more layers may be laminated. When two or more tin layers are laminated, the tin layers can be the same or different from each other in their properties and/or formation methods. The plural tin layers having the same composition of the constituent materials with each other are considered to be one layer.

The preferred layer number of the tin layers is one. When plural tin layers are laminated, the preferred range of the total metal amount applied and thickness of the multiple laminated tin layers is same as the above-described preferred range of metal amount applied and thickness of a single tin layer.

The method for forming the tin layer is not particularly limited. Examples of the methods for forming the tin layer include wet film formation methods such as electroless plating and electroplating. While either electroless plating or electroplating may be used, electroplating is preferred due to the ease of controlling film thickness and continuous processing.

In electroplating, when a single electroplating process is not sufficient to form a tin layer of the desired thickness, the electroplating process can be performed a plurality of times using a tin plating solution of the same composition for forming a tin layer of the desired thickness. That is, the process can be performed through the plural baths of tin plating solutions of the same composition.

For example, a tin layer of the desired thickness can be formed by preforming a first tin plating process followed by rinsing with water, then performing a second tin plating process using a tin plating solution having the same composition as the first tin plating process followed by rinsing with water, and then performing a third tin plating process using a tin plating solution having the same composition as the second tin plating process followed by rinsing with water. There is no particular limit to the number of processes for tin plating using tin plating solutions of the same composition. The number of processes can be adjusted appropriately to achieve the desired thickness. The tin layer of the desired thickness formed in this way can be considered to be one layer, since the composition of the materials constituting each layer is the same.

In the tin layer, the average grain size of the tin crystals constituting the tin layer is 5.0 μm or more. The upper limit of the average grain size is not particularly limited, but is preferably 10 μm or less. The average grain size of the tin crystals of 5 μm or more provides the advantage of being less likely to cause metal cracks during molding.

Examples of the methods for adjusting the crystal grain size of the tin layer include a method of adjusting the plating time appropriately during electroplating. When the plating time is short, the crystal growth might be insufficient and the grain size tends to be small. when the plating time is long, the crystal growth may be sufficient, and the grain size will tend to be large.

Furthermore, using a non-glossy tin plating solution as the plating solution enables to increase the grain size of the tin crystal. Since forming a tin layer using a glossy (=bright) tin plating solution makes the surface smoothed to give it a glossy finish, the crystal grain size of the resulting tin layer tends to be small and fine.

Examples of non-glossy tin plating solutions include, in particular, a tin plating solution that does not contain a brightener. Examples of the brighteners in this case include acrylic acid, methyl acrylate, methyl methacrylate, benzalacetone, benzaldehyde, and acetophenone. It is preferable to use a tin plating solution that does not contain these brighteners.

The arithmetic mean roughness Ra of the surface of the tin layer is preferably 0.25 μm or more. The surface of the tin layer mentioned here refers to the surface of the tin layer opposite to the surface on which the copper layer is formed, and is the outermost surface on the metal layer side of the conductive film of the present invention. There is no particular upper limit to the arithmetic mean roughness Ra, but is preferably 0.7 μm or less.

When the arithmetic mean roughness Ra of the tin layer is too small, starting points of cracks are more likely to occur which might cause large cracks. When the arithmetic mean roughness Ra of the tin layer is within the above range, cracks tend to be less likely to occur in the tin layer. The arithmetic mean roughness Ra of the tin layer refers to the surface roughness of the outermost metal layer of the conductive film after each layer is laminated, and can be measured after lamination using a method in accordance with JIS B 0601:2001.

In order to achieve the arithmetic mean roughness Ra of the tin layer within the above range, it is preferable to form the tin layer by electroplating using a non-glossy tin plating solution as the electroplating solution. Thus, the arithmetic mean roughness Ra of the surface of the tin layer can be increased.

### 3. Layer Structure

The conductive film of the present invention has at least a copper layer and a tin layer laminated in this order on a resin film. “In this order” means that the copper layer and the tin layer are laminated in this order from the side closest to the resin film. The copper layer and the tin layer may be laminated on one side of the resin film, or on both sides.

Examples of the layer structure of the conductive film of the present invention include [resin film/copper layer/tin layer], [resin film/copper layer (1)/copper layer (2)/tin layer], and [tin layer/copper layer/resin film/copper layer/tin layer]. Among them, the layer structure comprising “copper layer (1)” and “copper layer (2)” refers to an embodiment wherein plural copper layers having the same or different properties or formation methods are laminated. Examples of more preferred layer structure include [resin film/copper layer (vapor-deposited copper)/copper layer (electrolytically plated copper)/tin layer].

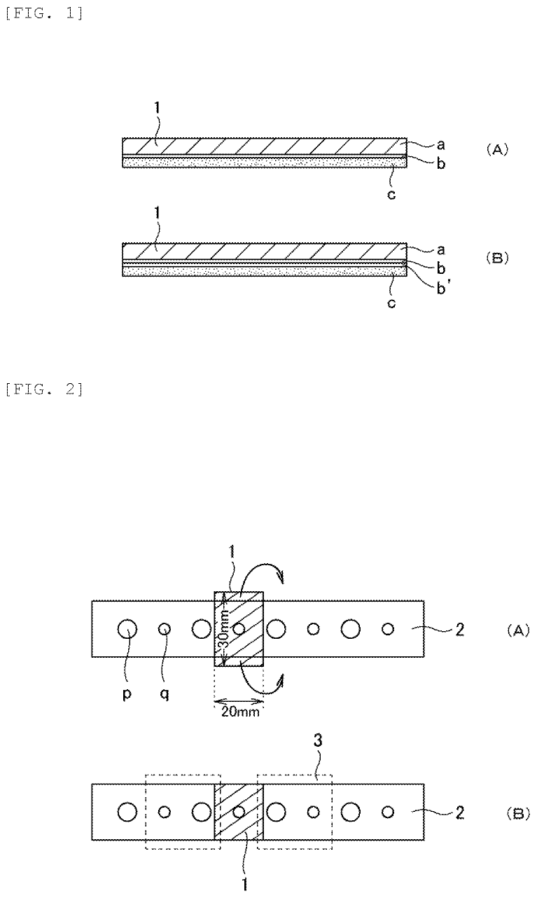

FIG. 1 shows a schematic diagram showing a cross-sectional view illustrating an embodiment of a conductive film of the present invention. FIG. 1(A) shows the layer structure of [resin film/copper layer/tin layer]. FIG. 1(B) shows the layer structure of [resin film/copper layer (1)/copper layer (2)/tin layer]. In FIG. 1(A), “a” shows the resin film, “b” shows the copper layer, and “c” shows the tin layer. In FIG. 1(B), “a” shows the resin film, “b” shows the copper layer (1), “b′” shows the copper layer (2), and “c” shows the tin layer.

In the conductive film of the present invention, in addition to the essential layers of the resin film which are copper layer and tin layer, various optional layers can be provided as needed. For example, an adhesive layer can be provided between each layer. In particular, an adhesive layer can be provided between the resin film and the copper layer to improve adhesion. Although the tin layer is the outermost layer of the conductive film, the surface thereof can be treated with an anti-tarnish agent to improve resistance to tarnish, or the like.

In the copper layer and tin layer of the conductive film of the present invention, the ratio of the amount of copper applied per unit area (g/m²) to the amount of tin applied per unit area (g/m²) [Cu/Sn] is 0.15 or less. When [Cu/Sn] is within this range, metal cracking is less likely to occur during molding. There is no particular lower limit for [Cu/Sn], but it is preferably 0.05 or more.

### 4. Manufacturing Method

The conductive film of the present invention can be manufactured by a method comprising a step of forming a copper layer on a resin film and a step of forming a tin layer by electrolytic tin plating on the copper layer formed in the previous step.

### (1) Step of Forming Copper Layer

The method for forming a copper layer on a resin film substrate is not particularly limited, and any known method can be used. Examples thereof include copper vapor deposition, electrolytic copper plating, and electroless copper plating. Among these, copper vapor deposition is preferred. Using a vapor deposition method for formation of the copper layer enables to obtain a copper layer excellent in surface smoothness.

Regarding formation of the copper layer, a method of forming a copper layer first by vapor deposition, and then forming an additional copper layer thereon by copper electroplating can be adopted, which enables a thicker copper layer to be formed more efficiently. In this case, the second copper layer formed by copper electroplating is laminated on the surface of the copper layer formed by vapor deposition. A commercially available resin film with a copper layer already formed thereon can also be used in the present invention.

In the case of forming a copper layer using electrolytic copper plating, when a single electroplating process is not sufficient to forma copper film of the desired thickness, a method of performing multiple times of electroplating using copper plating solutions having the same composition can be adopted for forming a copper layer of the desired thickness. That is, the copper plating solution can be passed through multiple baths of the same composition.

For example, a copper layer of the desired thickness can be formed by preforming a first copper plating process followed by rinsing with water, then performing a second copper plating process using a copper plating solution having the same composition as the first copper plating process followed by rinsing with water, and then performing a third copper plating process using a copper plating solution having the same composition as the second copper plating process followed by rinsing with water. There is no particular limit to the number of processes for copper plating using copper plating solutions having the same composition. The number of processes can be adjusted appropriately to achieve the desired thickness. The copper layer of the desired thickness formed in this way can be considered to be one layer, since the composition of the materials constituting the layer is the same.

### (2) Step of Forming Tin Layer

In the step of forming a tin layer on the copper layer, electrolytic tin plating can be adopted in which the tin plating layer can be formed using a standard electrolytic tin plating method. The plating solution used in the electrolytic tin plating can be an aqueous solution containing stannous sulfate or the like as a tin source. Commercially available electrolytic tin plating solutions can also be used.

It is preferable to use a non-glossy tin plating solution as the electrolytic tin plating solution, which allows a larger average grain size of the tin crystals and a larger arithmetic mean roughness (Ra) of the tin layer surface.

It is particularly preferable to restrict the addition of organic compounds that may be used in glossy tin plating solutions such as brighteners, examples of which include aldehyde compounds, amine compounds, and carboxylic acid (ester) compounds.

Specific examples of brighteners whose addition should be restricted include acrylic acid, methyl acrylate, methyl methacrylate, benzalacetone, benzaldehyde, and acetophenone. It is desirable to use a tin plating solution that does not contain these brighteners.

The conditions for electrolytic tin plating are not particularly limited, and they can be set within a range capable of forming a tin plating layer of the desired thickness. It is desirable to select conditions so that an average grain size of tin crystals in the tin layer becomes 5.0 μm or greater. Examples of preferred conditions include, but are not limited to, a plating solution temperature of 20-50° C., a current density of 0.5-5.0 A/dm², and a treatment time of 200-600 seconds.

### EXAMPLES

Hereinafter, the present invention will be described with reference to examples, but the present invention is not limited to these examples. The evaluations in the examples were performed according to the following methods.

### [Evaluation of Moldability]

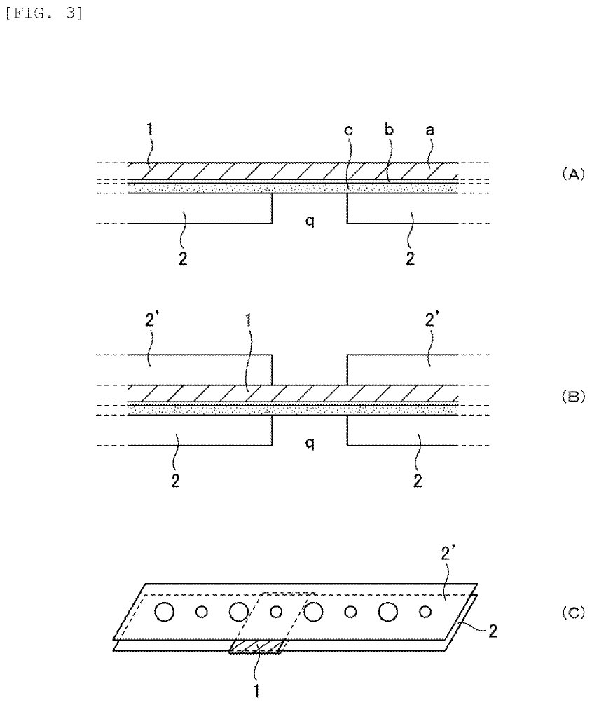

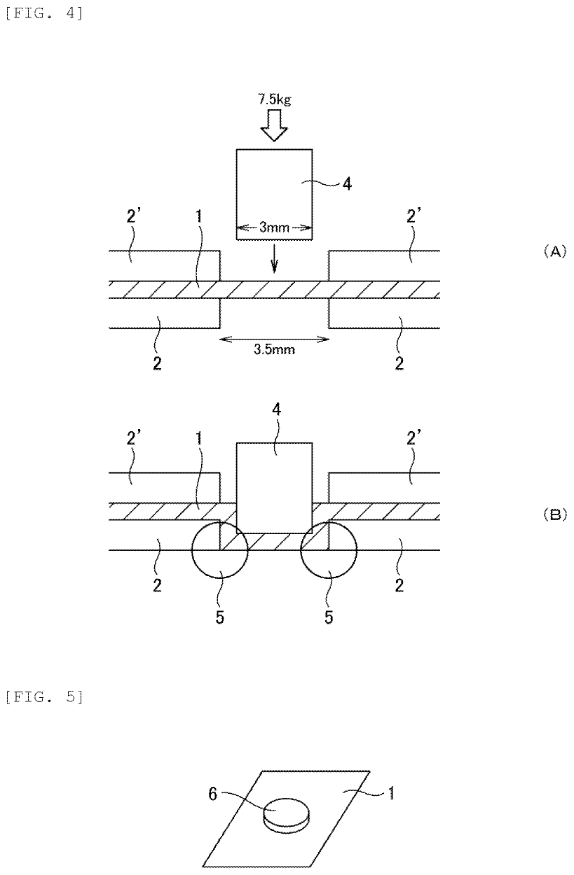

Samples (20 mm×30 mm) were cut from the conductive films prepared in Examples and Comparative Examples below, and were used for evaluation. Evaluation was performed according to the following processes based on the methods shown in FIGS. 2-5. FIG. 2 is a plan view showing a jig and a sample used in the evaluation of moldability, FIG. 3 is a cross-sectional view and schematic diagram showing the outline of a jig for fixing the sample for evaluation used in the evaluation of moldability, FIG. 4 is a cross-sectional view schematically showing the molding process, and FIG. 5 is a schematic diagram showing the conductive film after molding which is a molded product for evaluation sample.

In the drawings, the sample is shown as a conductive film having a layer structure of [resin film/copper layer/tin layer] as an embodiment, but is not limited to this layer structure as long as the layer structure falls within the scope of the present invention. For clarity and simplification, the dimensions in the drawings are not necessarily at an accurate ratio.

(1) A commercially available jig 2 in FIG. 2(A) which was a stainless steel curved plate with length 98 mm×width 20 mm×thickness 0.84 mm having four 5 mm diameter holes “p” and four 3.5 mm diameter holes “q”, a total hole number of eight, in a zigzag manner was prepared. The sample 1 in FIG. 2 (A) was placed in the jig so that the center of the sample overlapped the 3.5 mm holes. The sample was also placed so that the side having 20 mm width of the sample was aligned along the longitudinal direction of the jig, and the side having 30 mm width of the sample was aligned along the width direction of the jig. The portions of the sample on the 30 mm side that protruded beyond the jig on both sides were folded toward the back of the jig and secured in place by wrapping polyimide tape 3 in FIG. 2(B) across the width.

On the above jig 2, the sample 1 was fixed so that the resin film “a” was exposed on the surface and the tin layer “c” of the metal layer was in contact with the jig 2, see FIG. 3(A). When the jig 2 had a smooth edge side and a non-smooth edge side on the inner circle of the hole, the sample was fixed so that the smooth edge side was on top in contact with the metal layer “c” of the sample. By placing the smooth side on top, it is possible to avoid cracking of the sample at a location other than the location to be observed for metal cracks by the force applied to the inner edge of the hole at the time of placing the copper pin described below on top, which may result in light leakage at a location other than the location to be observed to cause a risk of obstructing the evaluation.

Another similar jig (jig 2′ in FIG. 3(B)) was placed on top of the sample-fixed jig thus obtained, so that the hole sizes and positions matched with the jig 2, see FIG. 3(B). The entire structure was then secured in place with polyimide tape to obtain a jig for fixing the sample for evaluation, see FIG. 3(C).

(2) The jig for fixing the sample for evaluation thus obtained was placed in a multi-oven, product name “MOV-300SB” manufactured byAS ONE Corporation, set to 230° C. and left to stand for 2 minutes.

After 2 minutes, a φ3.0 mm copper pin with a weight added to adjust the total weight to 7.5 kg which was a mold wherein a tray to which the mold was attached was weighted to adjust the total weight to 7.5 kg, see 4 in FIG. 4(A), was placed on the φ3.5 mm hole of the jig sandwiching the sample, and the sample was left to stand for 1 minute to be molded, see FIG. 4 (B). The jig for fixing the sample for evaluation was then taken out of the multi-oven followed by removing the sample from the jig to obtain a sample for evaluation as a molded product having a cylindrical protrusion-shaped molded part as shown in FIG. 5.

(3) In the sample molded product for evaluation having a cylindrical protrusion-shaped molded part formed by a copper pin with a weight placed thereon, the area formed by the bottom of the copper pin which was a circumferential portion of the cylindrical protrusion was observed for metal cracks using a digital microscope, product name “VHX-8000”, manufactured by KEYENCE Corporation. Only the area formed by the bottom of the copper pin was observed as an evaluation object for metal cracks (5 in FIG. 4 (B)) and the presence or absence of metal cracks in other areas was not taken into consideration.
(4) The sample molded product for evaluation was observed in a state being irradiated with light from behind which was a side opposite to the protruded side of the cylindrical protrusion-shaped molded part, using the digital microscope, product name “VHX-8000” manufactured by KEYENCE Corporation, to check for light leakage.
(5) Based on the presence or absence of metal cracks and light leakage, moldability was evaluated according to the following criteria:
Moldability ◯: No cracks in the metal layer, no light leakage.
Moldability Δ: No cracks in the metal layer, some light leakage.
Moldability Δ: Cracks in the metal layer, no light leakage.
Moldability x: Cracks in the metal layer, some light leakage.

### [Measuring the Metal Amount and Thickness of the Metal Layer (Copper Layer and Tin Layer)]

A sample was cut into a 3 cm×3 cm piece and immersed in 10 ml of half-diluted aqua regia to completely dissolve the metal layer to obtain a solution containing the dissolved metal layer. Then, the amount of copper (Cu) and tin (Sn) in this solution (units: mg/L) was measured using an atomic absorption spectrophotometer. The resulting metal amount (mg/L) was converted to a basis weight (g/m²) to determine the amount of metal applied. Furthermore, the amount of metal applied was converted to a thickness based on the specific gravity of each metal to determine the thickness (μm) of the each metal layer.

### [Average Grain Size of Tin Crystals]

The average grain size of the tin crystals in the tin layer was determined by the average line segment length obtained using the automatic area measurement: crystal grain size function of a digital microscope, product name “VHX-8000” manufactured by KEYENCE Corporation.

### [Measurement of Arithmetic Surface Roughness Ra]

Arithmetic surface roughness Ra was measured according to JIS B 0601:2001.

### Examples 1-4, 6

A resin film having a copper layer on one side formed by copper deposition using a conventional method, manufactured by Toray KP Films, Inc., hereafter referred to as “copper-deposited resin film” was prepared. The materials of the resin film in Table 1 are as follows:

[PEI]: Polyetherimide film having an elastic modulus of 3.2 GPa, a tensile strength of 110 MPa, a glass transition point of 215° C., and a melting point of 340° C.
[PPS]: Polyphenylene sulfide film having an elastic modulus of 3.5 GPa, a tensile strength of 80 MPa, a glass transition point of 90° C., and a melting point of 280° C.

The copper-deposited resin film was then acid-washed with 50 mL/L of an acid treatment solution containing sulfuric acid with a sulfuric acid concentration of 5% by volume (v/v). Then, it was immersed in a tin plating solution “A” of the composition shown below. Using a soluble tin anode, electrolytic tin plating was performed at 40° C. with a current density of 2.0 A/dm² for the treatment time (seconds) shown in Table 1, to form a tin layer on the surface of the copper-deposited layer of the copper-deposited resin film.

The film was then immersed in 50 mL/L of an anti-tarnish treatment solution, product name “501SN” manufactured by Ishihara Chemical Co., Ltd., at 40° C. for 60 seconds, to produce a conductive film having a layer structure of [resin film/copper layer/tin layer].

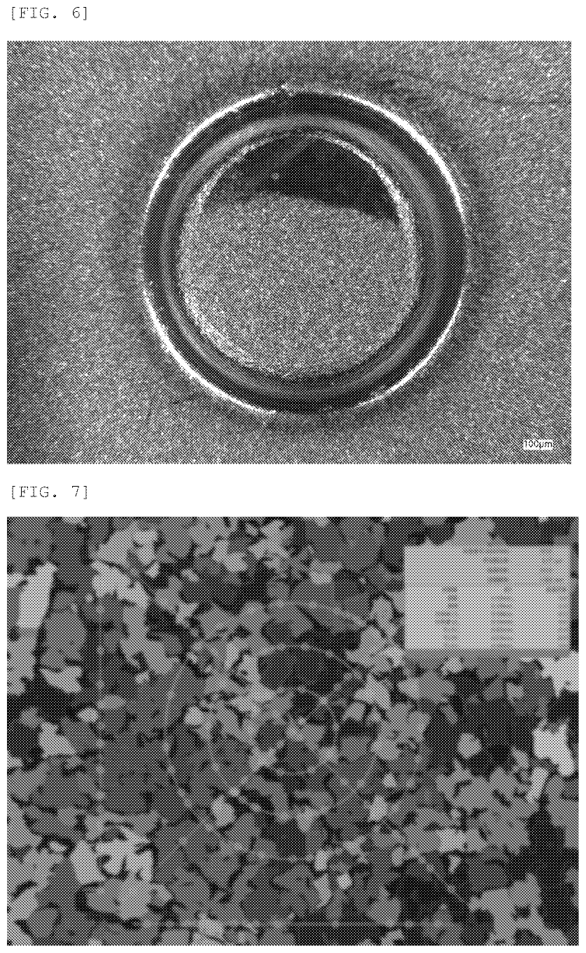

The results of an evaluation of moldability for the conductive films are shown in Table 1. FIG. 6 also shows a digital microscope image of the conductive film obtained in Example 1, in which the presence or absence of metal cracks was observed. FIG. 6 shows that the conductive film obtained in Example 1 did not have metal cracks in the molded part. Images of light leakage observed for the examples are not shown, as there was no light leakage and it appeared entirely black.

The average grain size of tin crystals in the tin layer of the conductive film thus obtained was measured, and the results are shown in Table 1. FIG. 7 shows a screen shot of the crystal grain size measurement taken with a digital microscope for the tin layer of the conductive film obtained in Example 1. FIG. 7 shows an average line segment length of 9.17 μm, which was determined to be the average crystal grain size in the tin layer of Example 1.

Note that the metal amounts applied and crystal grain sizes measured in Examples and Comparative Examples may vary slightly even when the manufacturing conditions for sample preparation and measurement conditions are the same, which may result in slight differences in the measured values.

### [Tin Plating Solution “A” ]

400 g/L of a tin component comprising the main component of tin methane sulfonate, product name “UTB PF-SN15”, manufactured by Ishihara Chemical Co., Ltd.
80 g/L of a conductive salt comprising the main component of methanesulfonic acid, product name “UTB PF-A”, manufactured by Ishihara Chemical Co., Ltd.
25 mL/L of a plating additive consisting of a methanesulfonic acid-based additive without comprising a brightener, product name “UTB PF-095SA”, manufactured by Ishihara Chemical Co., Ltd.

### Example 5

A conductive film was produced by forming a copper layer and a tin layer on the copper-vapor-deposited resin film shown in Table 1.

First, the copper-deposited resin film was acid-washed with an acid treatment solution as in Example 1, then immersed in the copper plating solution “a” having the composition described below. Using an insoluble anode, copper plating was performed at 40° C. with a current density of 2.5 A/dm² for the treatment time (seconds) shown in Table 1. The film was then immersed in 10 mL/L of a rust-prevention treatment liquid, product name “Pal C” manufactured by TATSUTA Electric Wire and Cable Co., Ltd., at 21° C. for 10 seconds to produce a copper laminate film having a layer structure of [resin film/copper layer/copper layer].

The copper laminate film thus obtained was then immersed in a tin plating solution “A” under the plating conditions shown in Table 1, and was subjected to tin plating in the same manner as in Example 1 to obtain a conductive film with a layer structure of [resin film/copper layer/copper layer/tin layer]. The moldability of the film thus obtained was evaluated, the results of which are shown in Table 1. Note that the thickness of the copper layer shown in Table 1 is the total thickness of the copper layers thus formed.

[Copper Plating Solution “a” ]
200 g/L of copper sulfate pentahydrate
55 mL/L of sulfuric acid having a concentration of 5.5% by volume (v/v)
85 mg/L of NaCl
25 mL/L of a soft copper film forming agent, product name “CU-SOFT” manufactured by JCU Co., Ltd.

### Comparative Examples 1 and 3

A conductive film with a layer structure of [resin film/copper layer/tin layer] was produced by forming a tin layer on the copper-deposited layer of the copper-deposited resin film in the same manner as in Example 1, except that the copper-deposited resin films shown in Table 2 were used and the conditions shown in Table 2 were adopted. The results are shown in Table 2.

### Comparative Example 2

The copper-deposited resin film shown in Table 2 was subjected to electrolytic tin plating using the following glossy tin plating solution “B” with a soluble tin anode at 21° C. with a current density of 2.0 A/dm² for the treatment time (seconds) shown in Table 2. The film was then immersed in 50 mL/L of an anti-tarnish treatment solution, product name “501SN”, manufactured by Ishihara Chemical Co., Ltd., at 40° C. for 60 seconds. A tin layer was formed on the copper-deposited layer in the same manner as in Example 1, except that the tin plating was performed under the conditions shown in Table 2 to produce a conductive film having a layer structure of [resin film/copper layer/tin layer]. The moldability of this film was evaluated, the results of which are shown in Table 2. Since a glossy tin plating solution was used, the crystal grain size of the tin layer was small.

### [Tin Plating Solution “B” ]

50 g/L of stannous sulfate component having a concentration of 5% by weight (w/v)
110 mL/L of sulfuric acid (concentration: 11% by volume (v/v));
50 mL/L of a bright (=glossy) tin plating additive, product name “ST-10”, manufactured by Ishihara Chemical Co., Ltd.

Note: “ST-10” is an additive containing the components necessary for bright tin plating, including polyoxyethylene nonylphenyl ether, pyrocatechol, methanol, etc., as well as methyl acrylate as a brightener.

### Comparative Examples 4-9

The copper-deposited resin film shown in Table 2 was acid-washed with an acid treatment solution as in Example 1, then immersed in the copper plating solution “a” having the above-described composition.

Using an insoluble anode, copper plating was performed at 40° C. with a current density of 2.5 A/dm² for the treatment time (seconds) shown in Table 2. The film was then immersed in 10 mL/L of an anti-corrosion treatment solution, product name “Pal C”, manufactured by TATSUTA Electric Wire and Cable Co., Ltd., at 21° C. for 10 seconds to obtain a copper laminate film with a layer structure of [resin film/copper layer/copper layer]. The thickness of the copper layer in Table 2 refers to the total thickness of the copper layers thus formed.

The copper laminate film thus obtained was then immersed in the tin plating solution “A” under the plating conditions shown in Table 2 to perform tin plating in the same manner as in Example 1, to produce a conductive film having a layer structure of [resin film/copper layer/copper layer/tin layer]. The moldability of the conductive film thus obtained was evaluated, the results of which are shown in Table 2.

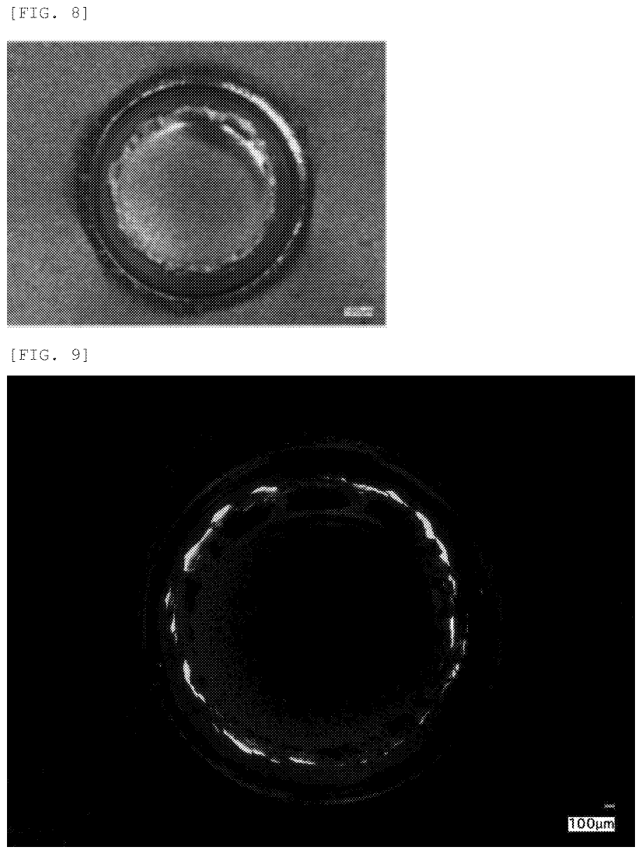

FIG. 8 shows a digital microscope image of the conductive film obtained in Comparative Example 5, in which the presence or absence of metal cracks was observed. According to FIG. 8, it can be seen that metal cracks occurred around the circumference of the cylindrical protrusion. FIG. 9 also shows a digital microscope image of the conductive film obtained in Comparative Example 5, in which the presence or absence of light leakage was observed. According to FIG. 9, it can be seen that light leakage, observed as whitish areas, occurred.

TABLE 1

| | | | Example 1 | Example 2 | Example 3 | Example 4 | Example 5 | Example 6 |
|---|---|---|---|---|---|---|---|---|
| Resin Film | | Material | PEI | PPS | PPS | PPS | PPS | PPS |
| | | Thickness of Resin | 125 | 125 | 125 | 125 | 125 | 125 |
| | | Film (μm) | | | | | | |
| Plating | Copper | Copper Plating | — | — | — | — | a | — |
| | | Solution | | | | | | |
| | | Treatment Time (sec) | — | — | — | — | 64 | — |
| | Tin | Tin Plating Solution | A | A | A | A | A | A |
| | | Treatment Time (sec) | 560 | 560 | 444 | 296 | 560 | 560 |

| Copper Layer | Amount Applied | 3.3 | 3.7 | 3.8 | 3.8 | 8.6 | 3.7 |
|---|---|---|---|---|---|---|---|
| | (g/m2) | | | | | | |
| | Thickness (μm) | 0.37 | 0.41 | 0.42 | 0.42 | 0.96 | 0.41 |
| Tin Layer | Amount Applied | 66.7 | 69.8 | 57.4 | 37.3 | 70.0 | 73.8 |
| | (g/m2) | | | | | | |
| | Grain Size (μm) | 9.17 | 9.34 | 7.33 | 5.44 | 9.37 | 7.26 |
| | Ra (μm) | 0.38 | 0.52 | 0.30 | 0.26 | 0.44 | 0.64 |

| | | | | | | |
|---|---|---|---|---|---|---|
| [Cu/Sn] | 0.05 | 0.05 | 0.07 | 0.10 | 0.12 | 0.05 |
| Metal Cracks | Absence | Absence | Absence | Absence | Absence | Absence |
| Light Leakage | Absence | Absence | Absence | Absence | Absence | Absence |
| Moldability | ◯ | ◯ | ◯ | ◯ | ◯ | ◯ |

TABLE 2

| | | | Comp. | Comp. | Comp. | Comp. | Comp. | Comp. | Comp. | Comp. | Comp. |
|---|---|---|---|---|---|---|---|---|---|---|---|
| | | | Example | Example | Example | Example | Example | Example | Example | Example | Example |
| | | | 1 | 2 | 3 | 4 | 5 | 6 | 7 | 8 | 9 |
| Resin Film | | Material | PEI | PPS | PPS | PPS | PPS | PPS | PPS | PPS | PPS |
| | | Thickness of Resin | 125 | 175 | 175 | 175 | 175 | 175 | 175 | 125 | 125 |
| | | Film (μm) | | | | | | | | | |
| Plating | Copper | Copper Plating | — | — | — | a | a | a | a | a | a |
| | | Solution | | | | | | | | | |
| | | Treatment Time (sec) | — | — | — | 119 | 302 | 64 | 119 | 302 | 119 |
| | Tin | Tin Plating Solution | A | B | A | A | A | A | A | A | A |
| | | Treatment Time (sec) | 560 | 580 | 118 | 560 | 560 | 118 | 270 | 118 | 160 |

| Copper Layer | Amount Applied | 11.5 | 3.3 | 3.5 | 12.3 | 24.5 | 8.3 | 13.7 | 26.6 | 13.3 |
|---|---|---|---|---|---|---|---|---|---|---|
| | (g/m2) | | | | | | | | | |
| | Thickness (μm) | 1.29 | 0.37 | 0.39 | 1.38 | 2.74 | 0.93 | 1.53 | 2.97 | 1.49 |
| Tin Layer | Amount Applied | 62.4 | 75.1 | 15.2 | 69.2 | 71.2 | 15.3 | 36.6 | 14.8 | 22.1 |
| | (g/m2) | | | | | | | | | |
| | Grain Size (μm) | 9.54 | 1.60 | 3.62 | 9.07 | 8.98 | 3.11 | 6.50 | 3.17 | 3.79 |
| | Ra (μm) | 0.47 | 0.04 | 0.11 | 0.51 | 0.32 | 0.12 | 0.19 | 0.13 | 0.16 |

| | | | | | | | | | |
|---|---|---|---|---|---|---|---|---|---|
| [Cu/Sn] | 0.18 | 0.04 | 0.23 | 0.18 | 0.34 | 0.54 | 0.37 | 1.80 | 0.60 |
| Metal Cracks | Presence | Presence | Presence | Presence | Presence | Presence | Presence | Presence | Presence |
| Light Leakage | Presence | Presence | Absence | Presence | Presence | Presence | Presence | Presence | Presence |
| Moldability | x | x | Δ | x | x | x | x | x | x |

### INDUSTRIAL APPLICABILITY

Since the conductive film of the present invention is lightweight and does not cause cracks in the metal layer even when subjected to molding processing, it is useful not only as an electromagnetic wave shielding material but also as a grounding material for noise removal.

### DESCRIPTION OF REFERENCE NUMERALS

1. Conductive film which is a sample for moldability evaluation
2. Jig for moldability evaluation
2′. Jig for moldability evaluation
3. Polyimide tape
4. Copper pin
5. Area to be observed for metal cracks in the molded part which is a circumferential portion of the cylindrical protrusion
6. Cylindrical protrusion-shaped portion of the sample molded product for evaluation
a. Resin film
b. Copper layer or copper layer (1)

1. A conductive film having a resin film and a metal layer in which a copper layer and a tin layer are laminated in this order on at least one side of said resin film, wherein the ratio of the amount of copper applied per unit area (g/m²) to the amount of tin applied per unit area (g/m²) [Cu/Sn] is 0.15 or less, and the average grain size of the tin crystals constituting the tin layer is 5.0 μm or more.

2. The conductive film according to claim 1, wherein the amount of copper applied per unit area in said copper layer is 10 g/m² or less.

3. The conductive film according to claim 1, wherein the arithmetic mean roughness Ra of the surface of said tin layer is 0.25 μm or more.

4. The conductive film according to claim 1, wherein the thickness of said resin film is in the range of 100 to 200 μm.

5. A method for producing the conductive film according to claim 1, which comprises a step of forming a copper layer on a resin film and a step of forming a tin layer by electrolytic tin plating on said copper layer formed in the previous step.

6. The method for producing a conductive film according to claim 5, wherein a non-glossy tin plating solution is used as the plating solution for said electrolytic tin plating.

7. A method for producing the conductive film according to claim 2, which comprises a step of forming a copper layer on a resin film and a step of forming a tin layer by electrolytic tin plating on said copper layer formed in the previous step.

8. A method for producing the conductive film according to claim 3, which comprises a step of forming a copper layer on a resin film and a step of forming a tin layer by electrolytic tin plating on said copper layer formed in the previous step.

9. A method for producing the conductive film according to claim 4, which comprises a step of forming a copper layer on a resin film and a step of forming a tin layer by electrolytic tin plating on said copper layer formed in the previous step.

10. The method for producing a conductive film according to claim 7, wherein a non-glossy tin plating solution is used as the plating solution for said electrolytic tin plating.

11. The method for producing a conductive film according to claim 8, wherein a non-glossy tin plating solution is used as the plating solution for said electrolytic tin plating.

12. The method for producing a conductive film according to claim 9, wherein a non-glossy tin plating solution is used as the plating solution for said electrolytic tin plating.
